(19) United States
(12) Patent Application Publication
(10) Pub. No.: US 2025/0266386 A1
(43) Pub. Date: Aug. 21, 2025

(54) Conductive Paste And Sintering Methods

(71) Applicant: Celanese Mercury Holdings Inc., Wilmington, DE (US)

(72) Inventor: Yuji Saga, Tochigi (JP)

(21) Appl. No.: 19/039,816

(22) Filed: Jan. 29, 2025

Related U.S. Application Data
(60) Provisional application No. 63/554,222, filed on Feb. 16, 2024.

(51) Int. Cl. H01L 23/00; B22F 1/103; B22F 7/06

(52) U.S. Cl. CPC H01L 24/29; B22F 1/103; B22F 7/064; H01L 24/83; B22F 2301/255; B22F 2304/054; B22F 2304/056; B22F 2304/058; B22F 2304/10; H01L 2224/29139; H01L 2224/8384

(57) ABSTRACT

A conductive paste is provided. The conductive paste includes a metal particulate material having a first metal powder having a having a D50 ranging from about 500 nm to about 1,500 nm, a second metal powder having a D50 ranging from about 10 nm to about 100 nm, and a third metal powder having a D50 ranging from about 3,000 nm to about 5,500 nm. The metal paste includes a solvent composition. The weight ratio of the third metal powder to the first metal powder is greater than 1. Electronic articles are also provided.

### RELATED APPLICATION

The present application is based upon and claims priority to U.S. Provisional Patent Application Ser. No. 63/554,222, having a filing date of Feb. 16, 2024, which is incorporated herein by reference.

### BACKGROUND OF THE DISCLOSURE

Solder connections or sintering technology are used for joining electronic components to a substrate. Sintered connections provide a sintered bond between parts having high temperature resistance while ensuring good electrical and thermal contact. However, processes for sintering electronic components together require sintering at high process temperatures and utilizing die bond equipment to pressurize the sintered arrangement, which increases manufacturing time, complexity, and cost.

Considering this, a need exists for improved conductive sintering materials and methods.

### SUMMARY OF THE DISCLOSURE

Aspects of the present disclosure include a conductive paste. The conductive paste includes a metal particulate material having a first metal powder having a having a D50 ranging from about 500 nm to about 1,500 nm, a second metal powder having a D50 ranging from about 10 nm to about 100 nm, and a third metal powder having a D50 ranging from about 3,000 nm to about 5,500 nm. The metal paste includes a solvent composition. The weight ratio of the third metal powder to the first metal powder is greater than 1.

Example aspects of the present disclosure are also directed to electronic articles including a semiconductor chip sintered to a substrate with a conductive paste. The conductive paste includes a metal particulate material having a first metal powder having a having a D50 ranging from about 500 nm to about 1,500 nm, a second metal powder having a D50 ranging from about 10 nm to about 100 nm, and a third metal powder having a D50 ranging from about 3,000 nm to about 5,500 nm. The metal paste includes a solvent composition. The weight ratio of the third metal powder to the first metal powder is greater than 1.

Other features and aspects of the present disclosure are set forth in greater detail below.

### BRIEF DESCRIPTION OF THE FIGURES

A full and enabling disclosure of the present disclosure, including the best mode thereof, directed to one of ordinary skill in the art, is set forth more particularly in the remainder of the specification, which makes reference to the appended figures in which:

FIG. 1 is a schematic view of an example method of forming a component arrangement according to one embodiment of the present disclosure; and

FIG. 2 is a flow chart of an example method of forming a component arrangement according to one embodiment of the present disclosure.

Repeat use of references characters in the present specification and drawing is intended to represent same or analogous features or elements of the disclosure.

### DETAILED DESCRIPTION

It is to be understood by one of ordinary skill in the art that the present discussion is a description of exemplary embodiments only and is not intended as limiting the broader aspects of the present disclosure.

Generally speaking, the present disclosure is directed to a conductive paste. The conductive paste includes one or more metal powders dispersed in a solvent composition. The one or more metal powders include a first metal powder having a having a D50 ranging from about 500 nm to about 1,500 nm, a second metal powder having a D50 ranging from about 10 nm to about 100 nm, and a third metal powder having a D50 ranging from about 3,000 nm to about 5,500 nm.

The present disclosure is also directed to a sintering method for joining at least two components. The method includes disposing a conductive paste on the first component. The conductive paste includes one or more metal powders dispersed in a solvent composition. The metal powder can include a first metal powder having a D50 ranging from about 500 nm to about 1,500 nm, a second metal powder having a D50 ranging from about 10 nm to about 100 nm, and a third metal powder having a D50 ranging from about 3,000 nm to about 5,500 nm. A second component is placed on the conductive paste and the component arrangement is sintered.

Advantageously, through selective control over the particular nature of the specific concentration of the components of the conductive paste, the present inventors have discovered that the resulting conductive paste can provide an effective sintered connection between component parts even when sintered at more rapid sintering times, such as sintering times about 90 minutes or less. Further, utilization of the conductive paste of the present disclosure reduces the need for a drying step prior to sintering. Thus, manufacturing complexities are reduced and improved processing rates can be realized. Additionally, utilization of the method provided herein provides a sintered connection with little to no void formation between the sintered components.

Various embodiments of the present disclosure will now be described in more detail.

### I. Conductive Paste

a. Metal Particulate Material

As indicated above, the conductive paste includes a metal particulate material. The metal particulate material of the present disclosure is not subject to any special limitation as long as it does not have an adverse effect on the technical effect of the present disclosure. The metal particulate material can include conductive materials with an electrical conductivity of about 7.00×10⁶ Siemens(S)/m or higher at 293 Kelvin in an embodiment, about 8.50×10⁶ S/m or higher at 293 Kelvin in another embodiment, about 1.00×10⁷ S/m or higher at 293 Kelvin in another embodiment, or about 4.00×10⁷ S/m or higher at 293 Kelvin in another embodiment. The metal particulate material can be a metal powder selected from the group consisting of aluminum (Al, 3.64×10⁷ S/m), nickel (Ni, 1.45×10⁷ S/m), copper (Cu, 5.81×10⁷ S/m), silver (Ag, 6.17×10⁷ S/m), gold (Au, 4.17×10⁷ S/m), molybdenum (Mo, 2.10×10⁷ S/m), magnesium (Mg, 2.30×10⁷ S/m), tungsten (W, 1.82×10⁷ S/m), cobalt (Co, 1.46×10⁷ S/m), zinc (Zn, 1.64×10⁷ S/m), platinum (Pt, 9.43×10⁶ S/m), palladium (Pd, 9.5×10⁶ S/m), alloys thereof and mixtures thereof.

In embodiments, the metal particulate material can be silver. In the case of using silver as the metal particulate material, it can be in the form of silver metal, silver derivatives and/or the mixture thereof. Examples of silver derivatives include silver oxide (Ag₂O), silver salts (such as silver chloride (AgCl), silver nitrate (AgNO₃), silver acetate (AgOOCCH₃), silver trifluoroacetate (AgOOCCF₃) or silver phosphate (Ag₃PO₄), silver-coated composites having a silver layer coated on the surface or silver-based alloys or the like.

The metal particulate material can be present in amounts ranging from about 90 wt. % to about 99 wt. %, such as about 92 wt. % to about 98 wt. %, such as from about 93 wt. % to about 97 wt. %, such as from about 94 wt. % to about 96 wt. %, based on the total weight of the conductive paste.

The metal particulate material can be in the form of a metal powder having metal particles of various shapes (for example, spherical shape, flakes, irregular form and/or the mixture thereof). In certain embodiments, the metal powder includes spherical particles. For instance, in embodiments, at least about 60% to about 100%, such as about 70% to about 90%, such as about 85% to about 100% of the metal particles are in the form of spherical particles.

The metal powder can include one or more metal powders each having a different and non-overlapping particle diameter (D50). The particle diameter (D50) can be measured by laser diffraction scattering method. For instance, in an embodiment the particle diameter (D50) can be measured by laser diffraction scattering method with Microtrac model S-3500. Other instruments known to be utilized to measure the particle diameter (D50) can also be used without departing from the scope of the present disclosure. Mixtures of metals having different average particle sizes, particle size distributions or shapes, etc. can also be employed. As used herein “D50” means that 50% of the particles are smaller than the recited size and that 50% of the particles are larger than the recited size.

The metal powder can include a first metal powder having a D50 ranging from about 500 nm to about 1,500 nm, such as from about 650 nm to about 1,200 nm, such as from about 1,000 nm to about 1,200 nm. The metal powder can include a second metal powder having a D50 ranging from about 10 nm to about 100 nm such as from about 20 nm to about 70 nm, such as from about 40 nm to about 80 nm. The metal powder can also include a third metal powder having a D50 ranging from about 3,000 nm to about 5,500 nm, such as from about 4,000 nm to about 5,000 nm, such as from about 4,400 nm to about 5,500 nm.

In one embodiment of the present disclosure, the first metal powder is present in an amount of about 15 wt. % to about 45 wt. %, such as from about 20 wt. % to about 30 wt. %, such as from about 30 wt. % to about 40 wt. % of the conductive paste. The second metal powder can be present in an amount of about 3 wt. % to about 15 wt. %, such as from about 5 wt. % to about 10 wt. %, such as from about 7 wt. % to about 12 wt. %. The third metal powder can be present in an amount of about 40 wt. % to about 75 wt. %, such as from about 50 wt. % to about 60 wt. %, such as from about 45 wt. % to about 67 wt. %.

The weight ratio of the third metal powder to the first metal powder is greater than 1. For instance, the weight ratio of the third metal powder to the first metal powder can be about 1.2:1 to about 7:1, such as about 1.2:1 to about 5:1, such as about 2:1 to about 6:1, such as about 3:1 to about 5:1. Further, the weight ratio of the third metal powder to the second metal powder is from about 3:1 to about 10:1, such as about 5:1 to about 9:1, such as about 6:1 to about 8:1. Still in other embodiments, the third metal powder is present in amounts of at least about 45 wt. % to about 75 wt. %, such as from about 45 wt. % to about 60 wt. %, such as from about 50 wt. % to about 70 wt. %, based on the total weight of the metal particulate material.

The metal particles in the powder can be coated with any suitable coating (e.g., surfactant). In embodiments, the metal particles are coated with a lipid, such as a fatty acid. The fatty acids can include free fatty acids, fatty acid salts, or fatty acid esters that can be branched, unbranched, saturated or unsaturated. Suitable fatty acids include, but are not limited to, oleic acid, stearic acid, lauric acid, caprylic acid, capric acid, myristic acid, palmitic acid, arachidic acid, behenic acid, lignoceric acid, cerotic acid, sorbic acid, and combinations thereof. In other embodiments, the metal particles can be coated with an anionic surfactant. Suitable anionic surfactants include sodium lauryl sulfate, sodium laureth sulfate, ammonium lauryl sulfate, ammonium laureth sulfate, sodium stearate, potassium cocoate, and combinations thereof. The coatings disclosed herein can be disposed on the surface of the metal particles by any means known in the art.

In embodiments, the conductive material is lead-free and does not contain lead or a lead component. Specifically, the conductive material is substantially free of any lead and the derivatives thereof (for example, lead oxides, such as lead monoxide (PbO), lead dioxide (PbO₂) or lead tetroxide (Pb₃O₄), and the like).

b. Solvent Composition

The conductive paste can include a solvent composition. For instance, the solvent composition can include one or more solvents in addition to other additives (e.g., dispersants). For instance, the metal powders can be mixed with the solvent composition to form a conductive paste. The solvent composition can be in a liquid or viscous form to facilitate mixing. Suitable solvent compositions allow the conductive material to be uniformly dispersed therein and have a proper viscosity to deliver the conductive material to the surface of an article such as by screen printing, stencil printing or the like. The conductive paste as provided also provides a good drying rate and excellent sintered properties even when sintered at lower pressures, decreased sintering time, or without additional drying steps prior to sintering. The solvent composition can be present in amounts ranging from about 1 wt. % to about 7 wt. %, such as from about 3 wt. % to about 5.5 wt. %, such as from about 4 wt. % to about 6 wt. %.

The solvent composition can include one or more suitable solvents. Suitable solvents can include alcohols (e.g., ethanols, diols, triols, fatty acid alcohols); esters (e.g., benzoic acid esters such as dibutylphthalate, dibasic ester), glycols (e.g., butyl carbitol, dibutyl carbitol, butyl carbitol acetate, hexylene glycol); hydrocarbons or mixtures of hydrocarbons (e.g., kerosene); and mixtures thereof. In embodiments, the solvent composition can include at least two different alcohols. In other embodiments, the solvent composition can include at least three different alcohols. The solvent can be present in an amount of about 1 wt. % to about 10 wt. %, such as from about 1 wt. % to about 7 wt. %, such as from about 3 wt. % to about 5 wt. %, such as from about 2.5 wt. % to about 5.5 wt. %, based on the total weight of the conductive paste.

The solvent composition can also include one or more dispersing agents. In some embodiments, the dispersing agent is selected from the group consisting of phosphated polyethers, phosphated polyesters, and mixtures thereof. In another embodiment, the dispersing agent is an alkylolammonium salt of a polyglycol ester. In another embodiment, the dispersing agent is selected from the group consisting of Disperbyk 180, an alkylolammonium salt of a polyglycol ester, Disperbyk 111, a phosphated polyester, Byk W-9010, a phosphated polyester or mixtures there of (all available from Byk-Chemie, GmBH, Wesel, Germany). In another embodiment, the dispersing agent is Solplus D540, a phosphated ethylene oxide/propylene oxide copolymer available from Lubrizol, Inc., Cleveland, Ohio. In yet another embodiment, the dispersing agent is a mixture of any of the above dispersing agents. In some embodiments, the dispersing agent is an aromatic polyamic acid or aromatic polyimide. In another embodiment the dispersing agent is a polyalkylene ether such as polytetramethylene glycol and polyethylene glycol.

The solvent composition can optionally include one or more additives. The additives can be one or more of a thickener, stabilizer, viscosity modifier, surfactant, wetting agent, thixotropic agent, flux agent and other conventional additives (for example colorants, preservatives, or oxidants), etc. In an embodiment, the solvent composition includes a flux agent. The amount of the additive depends on the desired characteristics of the resulting conductive paste. The selected additives are not subject to limitation as long as they do not adversely affect the technical effect of the present disclosure.

### II. Articles

The conductive paste can be applied to one or more components and utilized to sinter at least two components together. Notably, the conductive paste of the present disclosure can be applied to a first component, and then a second component can be disposed on the conductive paste forming a component arrangement. The conductive paste can then be sintered thus forming a sintered connection between the first component and the second component. The conductive paste can be utilized in a wide array of applications (e.g., power electronics, etc.) where an electrical connection having excellent adhesion is desired as further described and illustrated in the Examples provided hereinbelow. The component arrangement can include an electronic article whereby a sintered connection is formed via the conductive paste described herein between a semiconductor chip and a substrate.

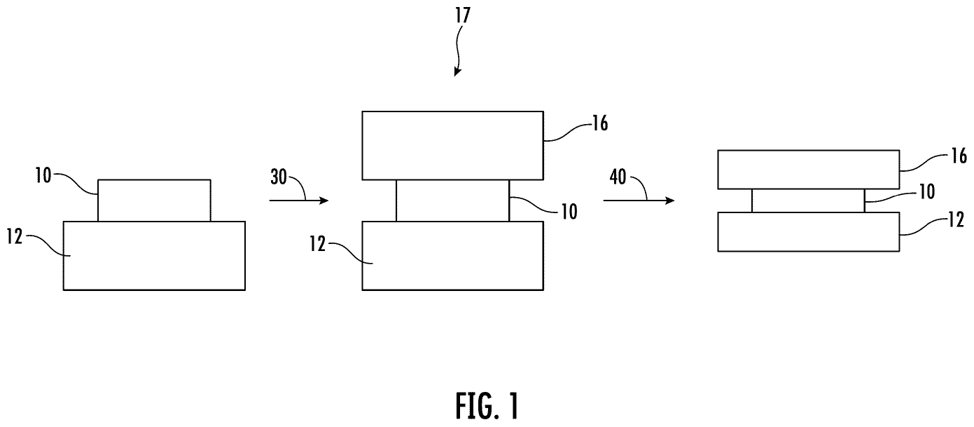

The conductive paste can be utilized to provide a sintered connection between component parts. For instance, as shown in FIG. 1, a conductive paste 10 is disposed on a substrate 12 (e.g., a first component). The substrate material can include any conductive, dielectric, or insulative material. Suitable substrates include printed circuit boards. The conductive paste 10 includes a solvent and is considered to be wet. The conductive paste 10 can be disposed on the substrate 12 via any suitable method including screen printing, stencil printing, dispense printing, or jet printing. At 30, a second component 16 is disposed on the conductive paste 10. The second component 16 can include a semiconductor chip or other suitable electronic component. The substrate 12, conductive paste 10, and the second component 16 form a component arrangement 17 that can be sintered, at 40. Notably, the component arrangement 17 can be sintered without the requiring additional drying steps prior to application of the second component 16 on the conductive paste 12. Further, in embodiments, the component arrangement can be sintered at a sintering pressure ranging from about 0 MPa to about 5 MPa. Further, in embodiments, the component arrangement 17 can be sintered without the use of a die or other equipment and can, instead, be sintered in any suitable oven that is capable of reaching the desired sintering temperature. Further, the component arrangement 17 can be sintered at a sintering temperature ranging from about 200° C. to about 350° C., such as from about 200° C. to about 280° C., such as from about 220° C. to about 280° C. such as from about 250° C. to about 300° C., such as from about 270° C. to about 290° C. The component arrangement can be sintered at a sintering time ranging from about 30 minutes to about 120 minutes, such as about 90 minutes or less.

After sintering, the component arrangement 17 can exhibit a shear strength of at least 20 MPa to about 60 MPa, such as at least about 30 MPa to about 50 MPa, such as at least about 40 MPa to about 50 MPa, as determined with a suitable shear tester. For instance, shear strength can be measured with a Dage 4000 shear tester available from Nordson Dage in the United Kingdom. To measure shear strength, the displacement of the shearing movement is measured by a tester and the corresponding shear strength is obtained, up to the maximum shearing force at the time of shearing fracture. The corresponding displacement value is recorded. For instance, the shear strength as used herein refers to the amount of force applied to peel the sintered components apart by pushing the first and second component in lateral directions.

### III. Methods

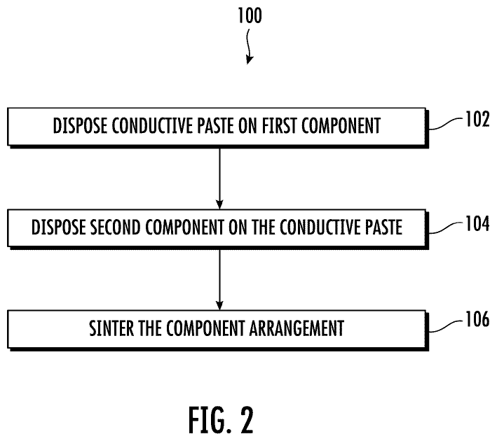

FIG. 2 depicts a flow diagram of one example method of forming an article (100) according to the present disclosure.

At (102), the method includes disposing a conductive paste on a first component. The conductive paste can include a conductive material and dispersed within a solvent composition. The conductive paste can include materials described hereinabove. In embodiments, the conductive material can include a metal powder, such as silver. The solvent composition can include one or more solvents (e.g., alcohols) and a dispersing agent. The conductive paste can include from about 3 wt. % to about 5.5 wt. % of the solvent composition and from about 90 wt. % to about 97 wt. % of metal powders.

At (104), the method includes disposing a second component on the conductive paste. In such an embodiment, a die can be used to join the first component having the conductive paste thereon to the second component. For instance, the first component having the conductive paste thereon can be disposed in the bottom of the die. The top and bottom of the die can then be used to press the first component and the second component together at a pressure of about 0.01 MPa to about 0.20 MPa, such as from about 0.05 MPa to about 0.10 MPa, for a time period of about 0.1 second to about 1 minute, such as from about 1 second to about 20 seconds. The first component, conductive paste, and second component form a component arrangement that can then be sintered.

At (106), the method includes sintering the component arrangement. The component arrangement can be sintered at a sintering temperature ranging from about 200° C. to about 400° C., such as from about 250° C. to about 350° C., such as from about 250° C. to about 300° C. The component arrangement can be sintered for a sintering time ranging from about 5 minutes to about 120 minutes, such as from about 15 minutes to about 90 minutes, such as from about 30 minutes to about 60 minutes. The component arrangement can be sintered in air or in an inert atmosphere containing an inert gas. In embodiments, the component arrangement can be sintered at a sintering pressure of about 0 MPa to about 5 MPa. Sintering the component arrangement can include exposing the component arrangement to an initial sintering temperature of about 25° C. and ramping up the temperature at a rate of about 3° C./min to about 10° C./min. to a final sintering temperature of about 200° C. to about 300° C. The component arrangement is held at the final sintering temperature of 250° C. for a time period of about 15 min to about 60 min. The component arrangement is then cooled by reducing the temperature by about 1° C./min. until a temperature of about 40° C. is achieved. Advantageously, the current method allows for a more rapid sintering process that does not require additional drying steps for the conductive paste prior to sintering. Thus, the disclosed method reduces processing time and cost.

### Examples

The present disclosure is further illustrated by, but is not limited to, the following examples.

The example conductive pastes were prepared by dispersing various silver powders in a mixture of an organic solvent and a polymer. The dispersion was carried out by mixing the components in a mixer followed by a three-roll mill.

Examples and Comparative Examples are illustrated in Table 1 below. For instance, Table 1 provides the D50 of the silver metal powders utilized in each example along with the amount of metal powder, solvent, and dispersant. All amounts are weight percentage in Table 1 unless otherwise specified.

TABLE 1

| | Example | | | | |
|---|---|---|---|---|---|
| | | | Comp. | Comp. | Comp. |
| | Ex. 1 | Ex. 2 | Ex. 1 | Ex. 2 | Ex. 3 |
| Silver powder | 36.1 | 21.6 | 43.4 | 36.1 | 70.4 |
| D50 = 800 Wt. % | | | | | |
| Silver powder | 11.4 | 6.8 | 13.7 | 11.4 | 22.2 |
| D50 = 60 Wt. % | | | | | |
| Silver powder | — | — | — | 47.5 | — |
| D50 = 2,230 Wt. % | | | | | |
| Silver powder | 47.5 | 66.2 | 38.0 | — | — |
| D50 = 4,490 Wt. % | | | | | |
| Flux | 0.5 | 0.5 | 0.5 | 0.5 | 0.5 |
| (2-N-butoxyethoxy) | | | | | |
| acetic acid | | | | | |
| Dispersant | 0.2 | 0.2 | 0.2 | 0.2 | 0.2 |
| Solplus D540 | | | | | |
| Solvent 1-Decanol | 1.5 | 2.0 | 1.5 | 1.5 | 3.0 |
| Solvent | 0.6 | 0.6 | 0.6 | 0.6 | 0.6 |
| 2-methylbutane- | | | | | |
| 2,3,4-triol | | | | | |
| Solvent | 2.1 | 2.0 | 2.1 | 2.1 | 3.0 |
| Terpinyloxyethanol | | | | | |
| Void creation | Not ob- | Not ob- | Ob- | Ob- | Ob- |
| | served | served | served | served | served |
| Die shear | 41 | 28 | 39 | 55 | 46 |
| Strength MPa | | | | | |

The example pastes were stencil printed by metal squeeze on to a substrate surface. The substrate was a copper substrate. Squares of conductive pastes were printed on the substrate by using an air pulse dispenser. A chip was then mounted on the conductive paste. The chip was mounted using a die bonder at room temperature (e.g., about 20-22° C.). The substrate having the conductive paste thereon was mounted into the bottom of the die bonder and the chip was mounted into the top of the die bonder. The die bonder pressed the substrate and chip together at a pressure of 0.07 MPa for a time period of about 10 seconds. The substrate, conductive paste, and chip were sintered in an air atmosphere at a sintering temperature of 250° C. at 0 MPa for a time period of 22 minutes. The chip and substrate were subjected to an initial sintering temperature of about 25° C. and the temperature was ramped up at a rate of about 6° C./min. to a final sintering temperature of about 250° C. The chip and substrate were held at the final sintering temperature of 250° C. for a time period of about 22 min. The chip and substrate were cooled by reducing the temperature by about 1° C./min. until a temperature of about 40° C. was achieved. The sintered thickness of the paste was about 45 μm.

After sintering the die shear strength between the chip and the copper plate for each example was measured after thermal cycling. The testing was done in accordance with a standard die shear test method (MIL STD-883) using a bond tester (4000 Plus, Nordson Advanced Technology Co., Ltd.). The die shear strength was defined as the strength when the copper chip was peeled off by the bond tester.

As depicted, it was observed that the representative examples did not have void creation during or after sintering whereas the comparative examples did form voids.

### Definitions

As used herein, ranges and amounts can be expressed as “about” a particular value or range. “About” is intended to also include the exact amount. Hence “about 5 percent” means “about 5 percent” and also “5 percent.” “About” means within typical experimental error for the application or purpose intended.

As used herein, “optional” or “optionally” means that the subsequently described event or circumstance does or does not occur, and that the description includes instances where said event or circumstance occurs and instances where it does not. For example, an optional component in a method or composition means that the component may be present or may not be present in the method or composition.

As used herein, the term “substantially free” means no more than an insignificant trace amount present and encompasses completely free (e.g., 0 molar % up to 0.01 molar %).

Chemical elements are discussed in the present disclosure using their common chemical abbreviation, such as commonly found on a periodic table of elements. For example, hydrogen is represented by its common chemical abbreviation H; helium is represented by its common chemical abbreviation He; and so forth.

All references to singular characteristics or limitations of the present disclosure shall include the corresponding plural characteristic or limitation, and vice versa, unless otherwise specified or clearly implied to the contrary by the context in which the reference is made.

The methods and compositions of the present disclosure, including components thereof, can comprise, consist of, or consist essentially of the essential elements and limitations of the disclosure described herein.

These and other modifications and variations of the present disclosure may be practiced by those of ordinary skill in the art, without departing from the spirit and scope of the present disclosure. In addition, it should be understood that aspects of the various embodiments may be interchanged both in whole or in part. Furthermore, those of ordinary skill in the art will appreciate that the foregoing description is by way of example only and is not intended to limit the disclosure so further described in such appended claims.

What is claimed is:

1. A conductive paste, comprising:
a metal particulate material comprising a first metal powder having a having a D50 ranging from about 500 nm to about 1,500 nm, a second metal powder having a D50 ranging from about 10 nm to about 100 nm, and a third metal powder having a D50 ranging from about 3,000 nm to about 5,500 nm; and
a solvent composition,
wherein the weight ratio of the third metal powder to the first metal powder is greater than 1.

2. The conductive paste of claim 1, wherein the conductive paste comprises from about 90 wt. % to about 99 wt. % of the metal particulate material and from about 1 wt. % to about 10 wt. % of the solvent composition.

3. The conductive paste of claim 1, wherein the weight ratio of the third metal powder to the first metal powder is from about 1.2:1 to about 5:1.

4. The conductive paste of claim 1, wherein the weight ratio of the third metal powder to the second metal powder is from about 3:1 to about 10:1.

5. The conductive paste of claim 1, wherein the first metal powder, the second metal powder, and the third metal powder comprise silver.

6. The conductive paste of claim 1, wherein the third metal powder comprises at least 45 wt. % to about 75 wt. % of the metal particulate material.

7. The conductive paste of claim 1, wherein each of the first metal powder, second metal powder, and third metal powder comprise spherical particles.

8. The conductive paste of claim 1, wherein each of the first metal powder, second metal powder, and third metal powder comprise a coating.

9. The conductive paste of claim 8, wherein the coating comprises one or more lipids.

10. The conductive paste of claim 1, wherein the solvent composition comprises one or more alcohols and a dispersant.

11. A sintering method for joining at least two components, the method comprising:
disposing a conductive paste on a first component, the conductive paste comprising:
a metal particulate material comprising a first metal powder having a D50 ranging from about 500 nm to about 1,500 nm, a second metal powder having a D50 ranging from about 10 nm to about 100 nm, and a third metal powder having a D50 ranging from about 3,000 nm to about 5,500 nm, wherein the weight ratio of the third metal powder to the first metal powder is greater than 1;
disposing a second component on the conductive paste to form a component arrangement; and
sintering the component arrangement.

12. The method of claim 11, comprising a sintering time of about 90 minutes or less.

13. The method of claim 11, wherein disposing the conductive paste on the first component comprises printing the conductive paste on the first component.

14. The method of claim 11, wherein disposing a second component on the conductive paste comprises disposing the first component having the conductive paste thereon on a bottom of a die, and pressing the first component and second component together at a pressure of about 0.01 MPa to about 1 MPa for a time period of about 0.1 seconds to about 10 seconds.

15. The method of claim 11, wherein sintering the component arrangement comprises exposing the component arrangement to an initial sintering temperature of about 25° C. and ramping up the temperature at a rate of about 3° C./min to about 10° C./min to a final sintering temperature of about 200° C. to about 300° C., which is held for about 15 min to about 60 min.

16. The method of claim 11, wherein the component arrangement exhibits a shear strength of at least about 10 MPa to about 60 MPa.

17. The method of claim 11, wherein the conductive paste comprises from about 90 wt. % to about 99 wt. % of the metal particulate material and from about 1 wt. % to about 10 wt. % of the solvent composition.

18. The method of claim 11, wherein the weight ratio of the third metal powder to the first metal powder is from about 1.2:1 to about 5:1.

19. The method of claim 11, wherein the weight ratio of the third metal powder to the second metal powder is from about 3:1 to about 10:1.

20. An electronic article comprising a semiconductor chip sintered to a substrate with a conductive paste comprising the conductive paste of claim 1.
